(19) United States
(12) Patent Application Publication
(10) Pub. No.: US 2025/0079176 A1
(43) Pub. Date: Mar. 6, 2025

(54) SEMICONDUCTOR DEVICE AND PRODUCTION METHOD FOR SEMICONDUCTOR DEVICE

(71) Applicant: SUMITOMO ELECTRIC INDUSTRIES, LTD., Osaka (JP)

(72) Inventor: Akihiro HAYASAKA, Osaka (JP)

(21) Appl. No.: 18/796,830

(22) Filed: Aug. 7, 2024

(30) Foreign Application Priority Data
Aug. 31, 2023 (JP) 2023-141123

(51) Int. Cl. H01L 21/28; H01L 21/02; H01L 29/20; H01L 29/423; H01L 29/51; H01L 29/66; H01L 29/778

(52) U.S. Cl. CPC H01L 21/28264; H01L 21/02181; H01L 21/02189; H01L 21/02192; H10D 64/685; H10D 64/693; H01L 21/02332; H10D 30/015; H10D 30/475; H10D 62/8503; H10D 64/516

(57) ABSTRACT

A production method for a semiconductor device includes: forming a dielectric oxide film on a nitride semiconductor layer, where the dielectric oxide film has a higher relative permittivity than a relative permittivity of silicon dioxide; nitriding the dielectric oxide film to form a dielectric oxynitride film; forming a first silicon nitride film on the dielectric oxynitride film by a thermal film formation method; forming a second silicon nitride film on the first silicon nitride film; forming an opening in the second silicon nitride film and the first silicon nitride film, where the opening reaches the dielectric oxynitride film; and forming a gate electrode on the second silicon nitride film, where the gate electrode is in contact with the dielectric oxynitride film through the opening.

### CROSS-REFERENCE TO RELATED APPLICATIONS

This patent application is based on and claims priority to Japanese Patent Application No. 2023-141123 filed on Aug. 31, 2023, the entire contents of which are incorporated herein by reference.

### TECHNICAL FIELD

The present disclosure relates to semiconductor devices and production methods for the semiconductor devices.

### BACKGROUND

There have been proposed high-electron-mobility transistors (HEMTs), each including a nitride semiconductor layer and a gate insulating film, where a top surface of the nitride semiconductor layer has a gallium (Ga)-polarity and the gate insulating film is a hafnium silicon oxynitride (HfSiON) film (see, for example, PCT Japanese Translation Patent Publication No. 2009-506537 and Japanese Patent Application Laid-Open No. 05-223855).

### SUMMARY

A production method for a semiconductor device according to one aspect of the present disclosure includes: forming a dielectric oxide film on a nitride semiconductor layer, where the dielectric oxide film has a higher relative permittivity than a relative permittivity of silicon dioxide; nitriding the dielectric oxide film to form a dielectric oxynitride film; forming a first silicon nitride film on the dielectric oxynitride film by a thermal film formation method; forming a second silicon nitride film on the first silicon nitride film; forming an opening in the second silicon nitride film and the first silicon nitride film, where the opening reaches the dielectric oxynitride film; and forming a gate electrode on the second silicon nitride film, where the gate electrode is in contact with the dielectric oxynitride film through the opening.

### BRIEF DESCRIPTION OF THE DRAWINGS

FIG. 1 is a cross-sectional view illustrating a semiconductor device according to the present embodiment;

FIG. 2 is a cross-sectional view (part 1) illustrating a production method for a semiconductor device according to the present embodiment;

FIG. 3 is a cross-sectional view (part 2) illustrating the production method for the semiconductor device according to the present embodiment;

FIG. 4 is a cross-sectional view (part 3) illustrating the production method for the semiconductor device according to the present embodiment;

FIG. 5 is a cross-sectional view (part 4) illustrating the production method for the semiconductor device according to the present embodiment;

FIG. 6 is a cross-sectional view (part 5) illustrating the production method for the semiconductor device according to the present embodiment;

FIG. 7 is a cross-sectional view (part 6) illustrating the production method for the semiconductor device according to the present embodiment;

FIG. 8 is a cross-sectional view (part 7) illustrating the production method for the semiconductor device according to the present embodiment; and

FIG. 9 is a cross-sectional view (part 8) illustrating the production method for the semiconductor device according to the present embodiment.

### DETAILED DESCRIPTION

### Problem to be solved by the Present Disclosure

In recent years, inhibition of current collapse has been strongly desired.

The present disclosure aims to provide a semiconductor device that can inhibit current collapse and a production method for such semiconductor device.

### Effects of the Present Disclosure

According to the present disclosure,

current collapse can be inhibited.

### Description of the Embodiments of the Present Disclosure

First, the embodiments of the present disclosure will be listed and described.

[1] A production method for a semiconductor device according to one aspect of the present disclosure includes: forming a dielectric oxide film on a nitride semiconductor layer, where the dielectric oxide film has a higher relative permittivity than a relative permittivity of silicon dioxide; nitriding the dielectric oxide film to form a dielectric oxynitride film; forming a first silicon nitride film on the dielectric oxynitride film by a thermal film formation method; forming a second silicon nitride film on the first silicon nitride film; forming an opening in the second silicon nitride film and the first silicon nitride film, where the opening reaches the dielectric oxynitride film; and forming a gate electrode on the second silicon nitride film, where the gate electrode is in contact with the dielectric oxynitride film through the opening.

The dielectric oxynitride film functions as a gate insulating film. The dielectric oxynitride film has a higher level of insulation and pressure resistance than a dielectric oxide film, thus the dielectric oxynitride film can minimize gate leakage. Moreover, since the first silicon nitride film is formed on the dielectric oxynitride film by a thermal film formation method before forming the second silicon nitride film, dissociation of nitrogen from the dielectric oxynitride film is inhibited during the formation of the second silicon nitride film. Therefore, current collapse due to dissociation of nitrogen from the dielectric oxynitride film can be inhibited.

[2] In [1], the dielectric oxide film may include at least one element selected from the group consisting of hafnium, lanthanum, and zirconium. In this case, the dielectric oxynitride film is more likely to have a high relative permittivity.

[3] In [2], the dielectric oxide film may further include at least one element selected from the group consisting of silicon and aluminum. In this case, the dielectric oxynitride film is more likely to have a high relative permittivity.

[4] In any one of [1] to [3], a surface of the nitride semiconductor layer facing the dielectric oxide film may have a nitrogen-polarity. In this case, a reduction in resistance is more likely to be achieved.

[5] In any one of [1] to [4], the first silicon nitride film may have a thickness of 0.2 nm or greater and 5 nm or less. When the thickness of the first silicon nitride film is less than 0.2 nm, it may become difficult to inhibit dissociation of nitrogen from the dielectric oxynitride film. When the thickness of the first silicon nitride film is greater than 5 nm, traps in the first silicon nitride film may potentially cause current collapse.

[6] In any one of [1] to [5], the nitriding of the dielectric oxide film and the forming of the first silicon nitride film may be performed in a same film-forming chamber. In this case, dissociation of nitrogen from the dielectric oxynitride film is readily inhibited before forming the first silicon nitride film.

[7] In any one of [1] to [6], the forming of the second silicon nitride film may be performed using a nitrogen plasma.

[8] A semiconductor device according to another aspect of the present disclosure includes a nitride semiconductor layer, a dielectric oxynitride film on the nitride semiconductor layer, a first silicon nitride film on the dielectric oxynitride film, a second silicon nitride film on the first silicon nitride film, an opening, which reaches the dielectric oxynitride film, formed in the second silicon nitride film and the first silicon nitride film, and a gate electrode, which is in contact with the dielectric oxynitride film through the opening, on the second silicon nitride film.

The first silicon nitride film can be formed by a thermal film formation method. Therefore, dissociation of nitrogen from the dielectric oxynitride film can be inhibited during formation of the first silicon nitride film. Moreover, the second silicon nitride film is disposed on the first silicon nitride film. Therefore, dissociation of nitrogen from the dielectric oxynitride film can be inhibited during formation of the second silicon nitride film. Accordingly, current collapse due to dissociation of nitrogen from the dielectric oxynitride film can be inhibited.

[9] In [8], the first silicon nitride film may have a lower hydrogen atom concentration than a hydrogen atom concentration of the second silicon nitride film. In the case where the first silicon nitride film is formed by a thermal film formation method and the second silicon nitride film is formed using a nitrogen plasma, the hydrogen atom concentration of the first silicon nitride film is more likely to become lower than the hydrogen atom concentration of the second silicon nitride film.

In [8] or [9], the first silicon nitride film may have a higher density than a density of the second silicon nitride film. In the case where the first silicon nitride film is formed by a thermal film formation method and the second silicon nitride film is formed using a nitrogen plasma, the density of the first silicon nitride film is more likely to become higher than the density of the second silicon nitride film.

### Details of the Embodiments of the Present Disclosure

Embodiments of the present disclosure will be described in detail hereinafter, but the present disclosure is not limited to the embodiments below. In the present specification and the drawings, components having substantially the same functional configurations are denoted by the same reference symbols, and a duplicate description thereof may be omitted. In the present disclosure, a “plan view” means that a target is viewed from the top.

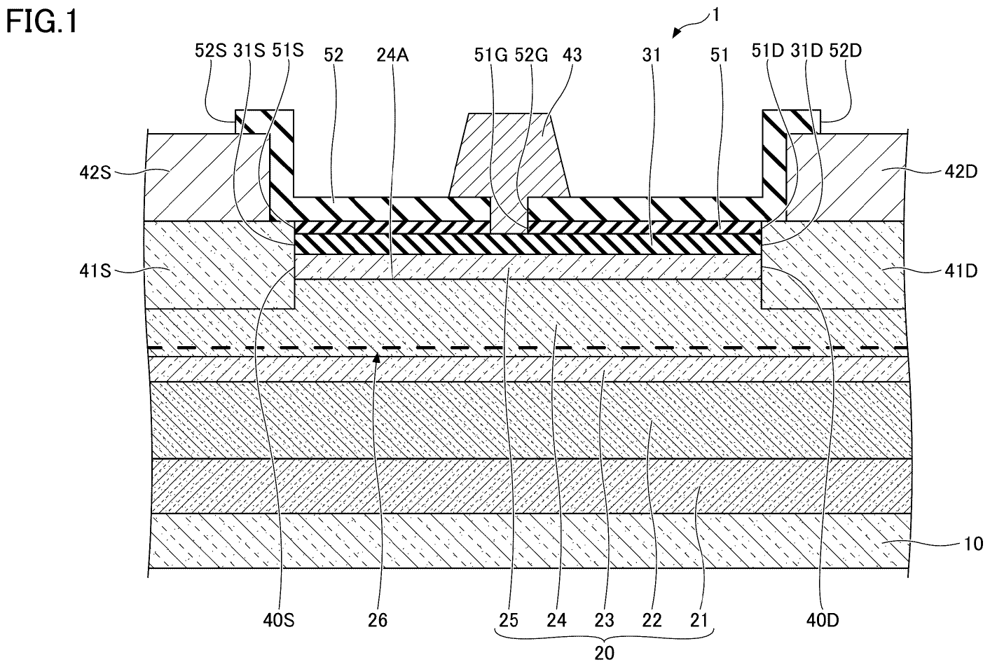

The present disclosure relates to a semiconductor device including a GaN-based high-electron-mobility transistor (HEMT). FIG. 1 is a cross-sectional view illustrating a semiconductor device according to the present disclosure.

As illustrated in FIG. 1, the semiconductor device 1 according to the present embodiment mainly includes a growth substrate 10, a nitride semiconductor layer 20, a dielectric oxynitride film 31, a first silicon nitride (SiN) film 51, a second SiN film 52, a regrowth layer 41S, a regrowth layer 41D, a gate electrode 43, a source electrode 42S, and a drain electrode 42D.

The growth substrate 10 is, for example, a semi-insulating silicon carbide (SiC) substrate. In the case where the growth substrate 10 is a SiC substrate, the top surface of the growth substrate 10 is a carbon (C)-face surface. In the case where the surface of the growth substrate 10 is a C-face surface, crystal growth of the nitride semiconductor layer 20 can occur with a nitrogen (N)-polar surface as a growth surface.

The nitride semiconductor layer 20 includes a buffer layer 21, a barrier layer 22, spacer layer 23, a channel layer 24, and a cap layer 25.

The buffer layer 21 is disposed on the growth substrate 10. The buffer layer 21 includes, for example, an aluminum nitride (AlN) layer. The thickness of the AIN layer is, for example, 1 nm or greater and 2,000 nm or less. The buffer layer 21 may include the AlN layer, and a GaN layer or aluminum gallium nitride (AlGaN) layer on the AlN layer.

The barrier layer 22 is disposed on the buffer layer 21. The barrier layer 22 includes, for example, an AlGaN layer. The band gap of the barrier layer 22 is greater than the band gap of the channel layer 24. The thickness of the barrier layer 22 is, for example, 1 nm or greater and 50 nm or less. The composition of the barrier layer 22 is, for example, Al_{y}Ga_{1-Y}N (0.15≤Y≤0.55). The conduction type of the barrier layer 22 is, for example, an n-type or an undoped type (i-type). A scandium aluminum nitride (ScAlN) layer, an indium aluminum nitride (InAlN) layer, or an indium aluminum gallium nitride (InAlGaN) layer may be used instead of the AlGaN layer.

The spacer layer 23 is disposed on the barrier layer 22. The spacer layer 23 includes, for example, an AlN layer. The thickness of the spacer layer 23 is, for example, in the range of 0.2 nm or greater and 5 nm or less.

The channel layer 24 is disposed on the spacer layer 23. The channel layer 24 includes, for example, a GaN layer. The band gap of the channel layer 24 is smaller than the band gap of the barrier layer 22. The thickness of the channel layer 24 is, for example, 1 nm or greater and 50 nm or less. A strain is generated between the channel layer 24 and a stack of the barrier layer 22 and the spacer layer 23 due to a difference in lattice constant, and the generated strain induces piezoelectricity at an interface between the channel layer 24 and the stack of the barrier layer 22 and the spacer layer 23. As a result, a two dimensional electron gas (2DEG) is formed inside the channel layer 24 in the vicinity of the surface of the channel layer 24 facing the barrier layer 22, thereby forming a channel region 26. The conduction type of the channel layer 24 is, for example, a n-type or an undoped type (i-type).

The cap layer 25 is disposed on the channel layer 24. The cap layer 25 includes, for example, an AlGaN layer. The thickness of the cap layer 25 is, for example, 0.2 nm or greater and 100 nm or less. The thickness may be 0.2 nm or greater and 10 nm or less.

On the C-face surface of the SiC substrate, crystal growth of the buffer layer 21, the barrier layer 22, the spacer layer 23, the channel layer 24, and the cap layer 25 occurs with a N-polar surface as a growth surface. Accordingly, each of the buffer layer 21, the barrier layer 22, the spacer layer 23, the channel layer 24, and the cap layer 25 has a N-polar surface as an top surface, and a gallium (Ga)-polar surface as a bottom surface.

A recess 40S for a source and a recess 40D for a drain are formed in the nitride semiconductor layer 20. The bottom of the recess 40S and the bottom of the recess 40D are closer to the bottom surface of the nitride semiconductor layer 20 than the top surface 24A of the channel layer 24. Specifically, the recess 40S and the recess 40D are formed to be deeper than the position of the top surface 24A of the channel layer 24. The bottom of the recess 40S and the bottom of the recess 40D may be located within the channel layer 24, within the spacer layer 23, or within the barrier layer 22.

The dielectric oxynitride film 31 is disposed on the nitride semiconductor layer 20. The dielectric oxynitride film 31 is in contact with the top surface of the nitride semiconductor layer 20. The relative permittivity of the dielectric oxynitride film 31 is greater than the relative permittivity of silicon dioxide (SiO₂). The dielectric oxynitride film 31 is a high-k film. The dielectric oxynitride film 31 may include at least one element selected from the group consisting of hafnium (Hf), lanthanum (La), and zirconium (Zr). Moreover, the dielectric oxynitride film 31 may further include at least one element selected from the group consisting of silicon (Si) and aluminum (Al). For example, the dielectric oxynitride film 31 is a hafnium silicon oxynitride (HfSiON) film or a hafnium aluminum oxynitride (HfAlON) film. The thickness of the dielectric oxynitride film 31 includes, for example, 1 nm or greater and 30 nm or less. An opening 31S for a source and an opening 31D for a drain are formed in the dielectric oxynitride film 31. The opening 31S is continuous with the recess 40S, and the opening 31D is continuous with the recess 40D.

The first SiN film 51 is disposed on the dielectric oxynitride film 31. The first SiN film 51 may include oxide in the vicinity of the interface between the first SiN film 51 and the dielectric oxynitride film 31. Accordingly, the first SiN film 51 may partially include silicon oxynitride (SiON) as such oxide. The first SiN film 51 is in contact with the top surface of the dielectric oxynitride film 31. The dielectric oxynitride film 31 is interposed between the nitride semiconductor layer 20 and the first SiN film 51, and the first SiN film 51 is isolated from the nitride semiconductor layer 20 by the dielectric oxynitride film 31. The thickness of the first SiN film 51 is, for example, 0.2 nm or greater and 5 nm or less. An opening 51S for a source, an opening 51D for a drain, and an opening 51G for a gate are formed in the first SiN film 51. The opening 51S is continuous with the opening 31S, and the opening 51D is continuous with the opening 31D. In a plan view, the opening 51G is located between the opening 51S and the opening 51D. Part of the dielectric oxynitride film 31 is exposed from the opening 51G.

The regrowth layer 41S is disposed on the channel layer 24, the spacer layer 23, or the barrier layer 22 within the recess 40S. The regrowth layer 41D is disposed on the channel layer 24, the spacer layer 23, or the barrier layer 22 within the recess 40D. Each of the regrowth layer 41S and the regrowth layer 41D includes, for example, a n-type GaN layer. The regrowth layer 41S and the regrowth layer 41D include germanium (Ge) or Si as n-type impurities. The electrical resistance of each of the regrowth layer 41S and the regrowth layer 41D is lower than the electrical resistance of the channel layer 24. For example, the regrowth layer 41S and the regrowth layer 41D are formed by regrowth of the n-type GaN layer after formation of the recess 40S and the recess 40D in the nitride semiconductor layer 20.

The source electrode 42S is disposed on the regrowth layer 41S, and the drain electrode 42D is disposed on the regrowth layer 41D. The source electrode 42S is in contact with the regrowth layer 41S, and the drain electrode 42D is in contact with the regrowth layer 41D. The source electrode 42S and the regrowth layer 41S form an ohmic contact, and the drain electrode 42D and the regrowth layer 41D form an ohmic contact.

The second SiN film 52 covers the first SiN film 51, the regrowth layer 41S, the regrowth layer 41D, the source electrode 42S, and the drain electrode 42D. As the second SiN film 52, for example, the portion of the second SiN film 52 having a uniform thickness on the first SiN film 51 has the thickness of 5 nm or greater and 100 nm or less. An opening 52S for a source, an opening 52D for a drain, and an opening 52G for a gate are formed in the second SiN film 52. Part of the source electrode 42S is exposed from the opening 52S, and part of the drain electrode 42D is exposed from the opening 52D. The opening 52G is continuous with the opening 51G.

In a plan view, the gate electrode 43 is located between the source electrode 42S and the drain electrode 42D. The gate electrode 43 is disposed on the second SiN film 52, the first SiN film 51, and the dielectric oxynitride film 31, and is in contact with the dielectric oxynitride film 31 through the opening 52G and the opening 51G.

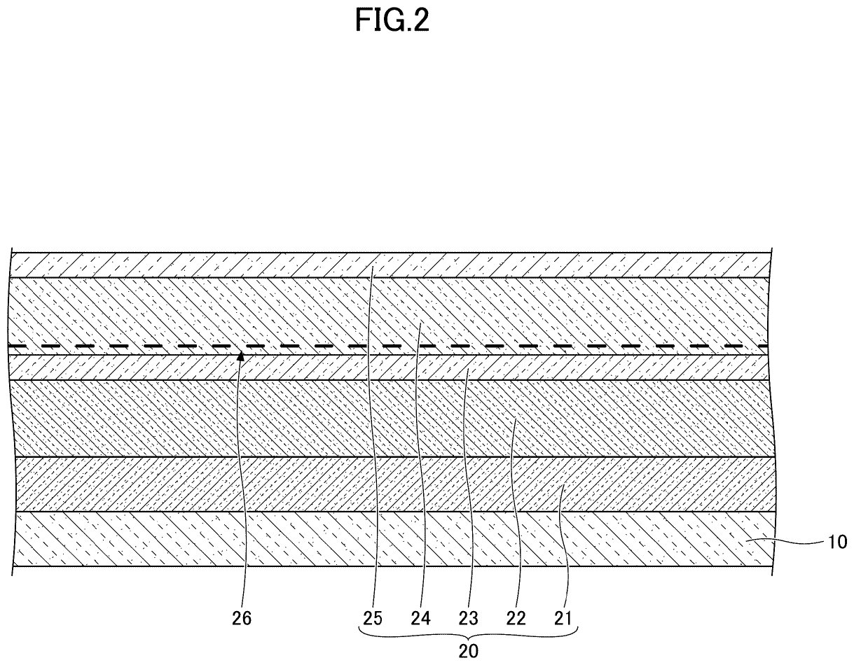

Next, the production method for the semiconductor device 1 according to the present embodiment will be described. FIGS. 2 to 9 are cross-sectional views illustrating the production method for the semiconductor device 1 according to the present embodiment.

First, as illustrated in FIG. 2, a nitride semiconductor layer 20 is formed on a growth substrate 10 by metal organic chemical vapor deposition (MOCVD). During the formation of the nitride semiconductor layer 20, a buffer layer 21, a barrier layer 22, a spacer layer 23, a channel layer 24, and a cap layer 25 are sequentially formed.

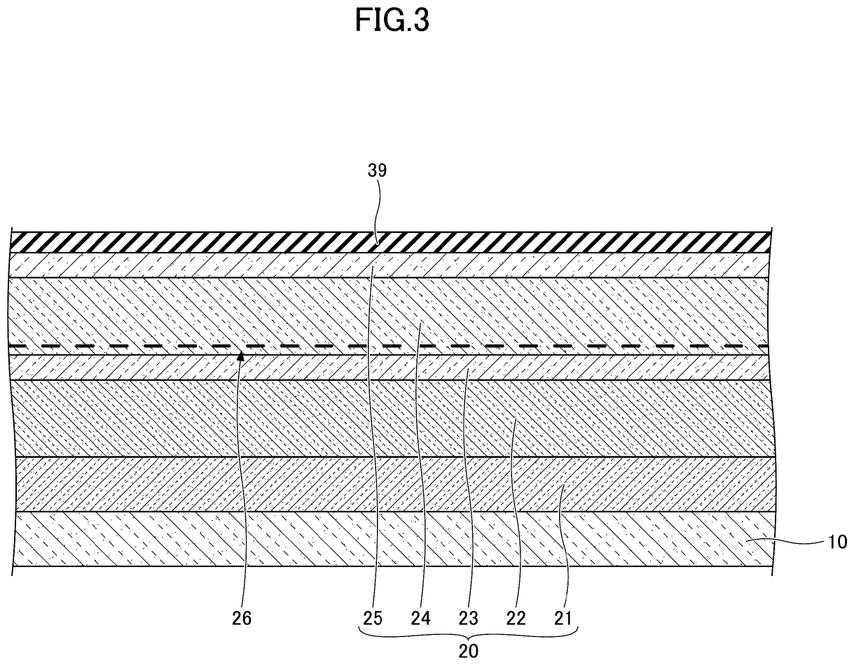

Next, as illustrated in FIG. 3, a dielectric oxide film 39 is formed on the nitride semiconductor layer 20. The dielectric oxide film 39 can be formed, for example, by atomic layer deposition (ALD). The dielectric oxide film 39 is in contact with the top surface of the nitride semiconductor layer 20. The relative permittivity of the dielectric oxide film 39 is greater than the relative permittivity of silicon dioxide (SiO₂). The dielectric oxide film 39 is a high-k film. The dielectric oxide film 39 may include at least one element selected from the group consisting of Hf, La, and Zr. Moreover, the dielectric oxide film 39 may further include at least one element selected from the group consisting of Si and Al. For example, the dielectric oxide film 39 is a hafnium silicate (HfSiO_{X}) film or a hafnium aluminate film (HfAlO_{X}) film. The thickness of the dielectric oxide film 39 is, for example, 1 nm or greater and 30 nm or less.

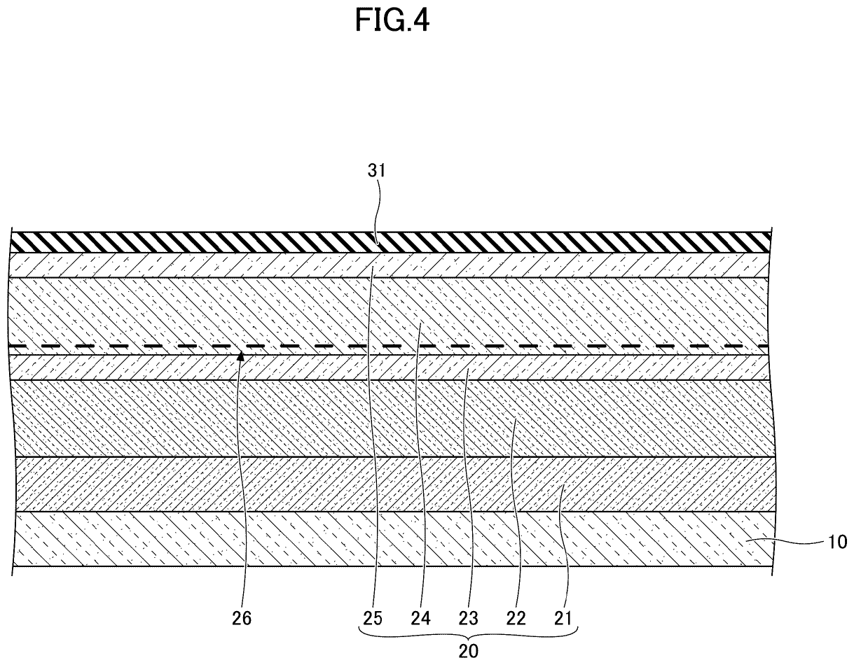

Next, as illustrated in FIG. 4, nitridation of the dielectric oxide film 39 is performed to form a dielectric oxynitride film 31. The nitridation of the dielectric oxide film 39 is performed, for example, inside a chamber of a film forming device, such as a MOCVD device or the like. As the N source for nitriding the dielectric oxide film 39, for example, N atoms generated, for example, through thermal decomposition of ammonia (NH₃) are used.

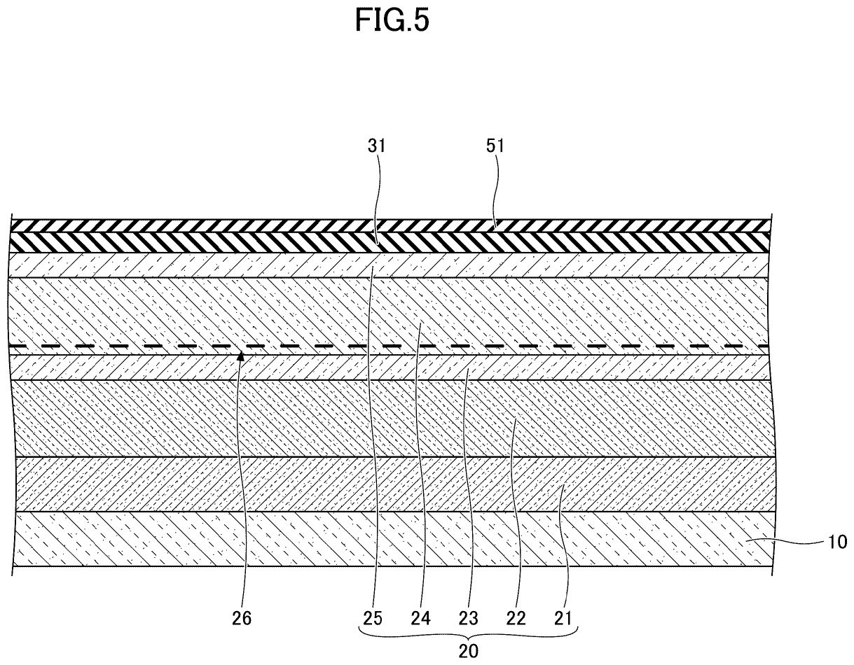

Next, as illustrated in FIG. 5, a first SiN film 51 is formed on the dielectric oxynitride film 31 by a thermal film formation method, such as thermal chemical vapor deposition (thermal CVD) or the like. The first SiN film 51 is formed in the same chamber as the chamber used for the nitridation of the dielectric oxide film 39. As raw materials of the first SiN film 51, for example, silane (SiH₄) and NH₃ are used.

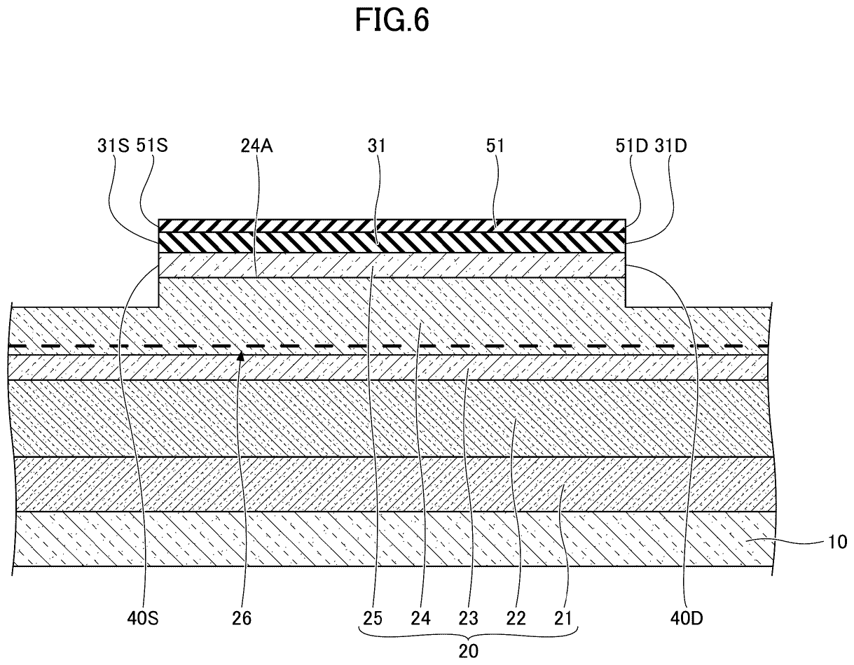

Next, as illustrated in FIG. 6, an opening 51S for a source and an opening 51D for a drain are formed in the first SiN film 51, an opening 31S for a source and an opening 31D for a drain are formed in the dielectric oxynitride film 31, and an recess 40S for a source and a recess 40D for a drain are formed in the nitride semiconductor layer 20. The bottom of the recess 40S and the bottom of the recess 40D may be closer to the bottom surface of the nitride semiconductor layer 20 than the top surface 24A of the channel layer 24. Specifically, the recess 40S and the recess 40D may be formed to be deeper than the position of the top surface 24A of the channel layer 24. The bottom of the recess 40S and the bottom of the recess 40D may be located within the channel layer 24, within the spacer layer 23, or within the barrier layer 22.

The opening 51S, the opening 51D, the opening 31S, the opening 31D, the recess 40S, and the recess 40D can be formed, for example, by reactive ion etching (RIE) using a mask (not illustrated). For example, a fluorine (F)-based gas is used as a reactive gas for formation of the opening 51S and the opening 51D, and a chlorine (Cl)-based gas is used as a reactive gas for formation of the opening 31S, the opening 31D, the recess 40S, and the recess 40D.

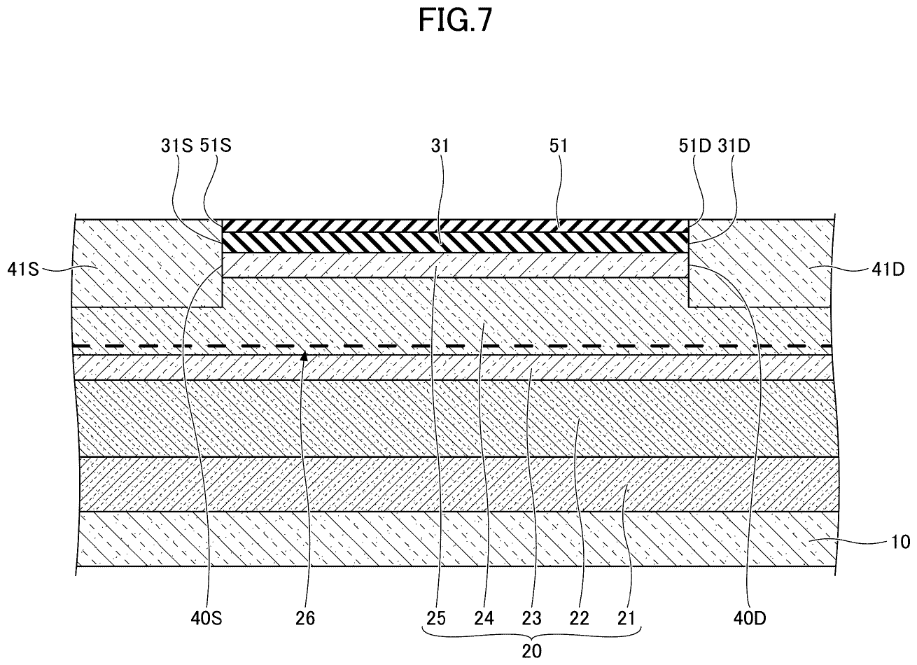

Next, as illustrated in FIG. 7, a regrowth layer 41S is formed on the channel layer 24, the spacer layer 23, or the barrier layer 22 inside the recess 40S, and a regrowth layer 41D is formed on the channel layer 24, the spacer layer 23, or the barrier layer 22 inside the recess 40D. The regrowth layer 41S and the regrowth layer 41D can be formed, for example, by physical vapor deposition (PVD), such as vapor deposition, sputtering, molecular beam epitaxy (MBE) or the like. The regrowth layer 41S and the regrowth layer 41D may be formed, for example, by MOCVD.

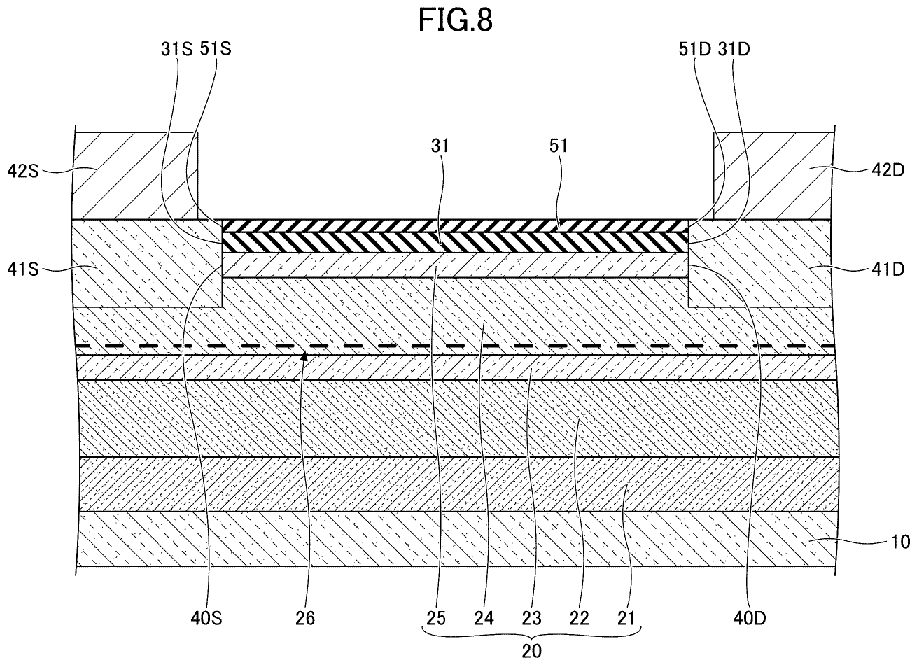

Next, as illustrated in FIG. 8, a source electrode 42S is formed on the regrowth layer 41S, and a drain electrode 42D is formed on the regrowth layer 41D. For the formation of the source electrode 42S and the drain electrode 42D, first, a metal layer (not illustrated) constituting the source electrode 42S and the drain electrode 42D is formed. During the formation of the metal layer, for example, film formation of the metal layer is carried out using a growth mask (not illustrated) in which openings are formed in corresponding regions where the metal layer is to be formed, followed by removing the growth mask together with the metal layer (not illustrated) formed on the growth mask. Specifically, lift-off is carried out.

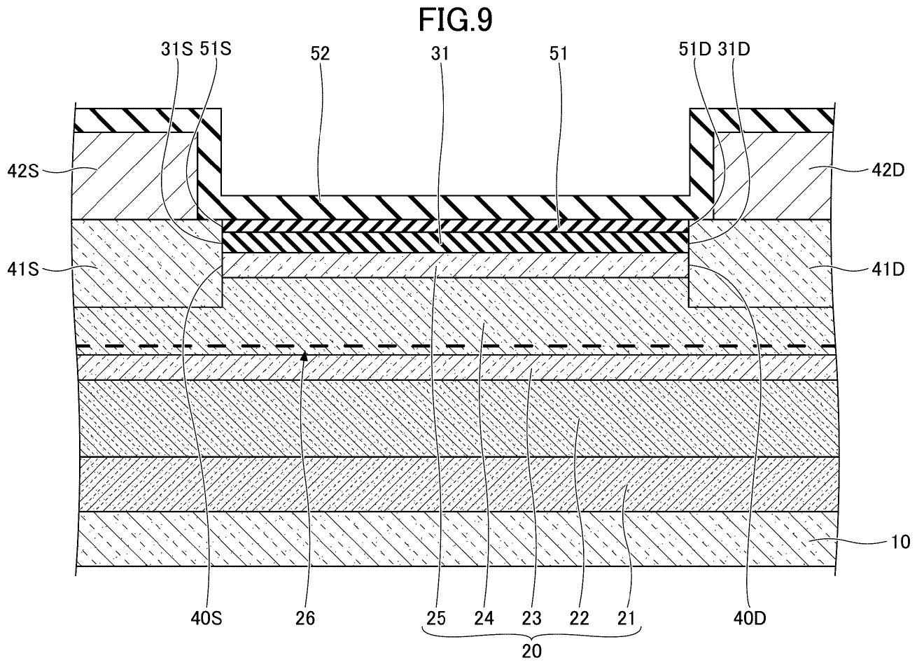

Next, as illustrated in FIG. 9, a second SiN film 52 is formed on the first SiN film 51, the regrowth layer 41S, the regrowth layer 41D, the source electrode 42S, and the drain electrode 42D. The second SiN film 52 covers the first SiN film 51, the regrowth layer 41S, the regrowth layer 41D, the source electrode 42S, and the drain electrode 42D. The second SiN film 52 is formed, for example, by plasma-enhanced chemical vapor deposition (PECVD). Specifically, the second SiN film 52 is formed, for example, using a nitrogen plasma.

Next, an opening 52G for a gate is formed in the second SiN film 52, and an opening 51G for a gate is formed in the first SiN film 51 (see FIG. 1). The opening 52G and the opening 51G can be formed, for example, by RIE using a mask (not illustrated). For the formation of the opening 52G and the opening 51G, for example, an F-based gas is used as a reactive gas.

Next, a gate electrode 43, which is in contact with the dielectric oxynitride film 31 through the opening 52G and the opening 51G, is formed on the second SiN film 52 (see, FIG. 1). During the formation of the gate electrode 43, film formation of the metal layer is carried out, for example, using a growth mask (not illustrated) in which an opening is formed in a region where the gate electrode 43 is to be formed, followed by removing the growth mask together with the metal layer (not illustrated) formed on the growth mask. Specifically, lift-off is carried out.

Next, an opening 52S for a source and an opening 52D for a drain are formed in the second SiN film 52 (see FIG. 1). The opening 52S and the opening 52D can be formed, for example, by RIE using a mask (not illustrated). For the formation of the opening 52S and the opening 52D, for example, an F-based gas is used as a reactive gas.

In the manner as described above, the semiconductor device 1 can be produced.

In the semiconductor device 1 according to the present embodiment, the dielectric oxynitride film 31 functions as a gate insulating film, and the second SiN film 52 functions as a passivation film. Moreover, the first SiN film 51 formed by a thermal film formation method inhibits dissociation of nitrogen from the dielectric oxynitride film 31 when the second SiN film 52 is formed by PECVD. According to the present embodiment, current collapse due to the dissociation of the nitrogen from the dielectric oxynitride film 31 can be therefore inhibited.

In the case where the second SiN film 52 is formed using a nitrogen plasma, the second SiN film 52 can be formed at a relatively low temperature. Thus, a metal material, which cannot be typically used in the formation of the second SiN film 52 by thermal CVD in view of a melting point or the like, can be used for the source electrode 42S and the drain electrode 42D. Moreover, use of PECVD can improve the throughput compared to thermal CVD.

The first SiN film 51 formed by a thermal film formation method and the second SiN film 52 forming using a nitrogen plasma are different from each other as described below. Specifically, the hydrogen (H)-atom concentration of the first SiN film 51 is more likely to become lower than the H-atom concentration of the second SiN film 52. Moreover, the density of the first SiN film 51 is more likely to become higher than the density of the second SiN film 52. The H-atom concentration in the first SiN film 51 and the H-atom concentration in the second SiN film 52 can be measured, for example, by Fourier transform infrared spectroscopy (FTIR). Moreover, the density of the first SiN film 51 and the density of the second SiN film 52 can be measured, for example, by X-ray reflectivity (XRR).

Since the dielectric oxide film 39 includes at least one element selected from the group consisting of hafnium, lanthanum, and zirconium, the dielectric oxynitride film 31 is more likely to have a high relative permittivity. Since the dielectric oxide film 39 further includes at least one element selected from the group consisting of silicon and aluminum, moreover, the dielectric oxynitride film 31 is more likely to have a high relative permittivity.

Since the surface of the nitride semiconductor layer 20 facing the dielectric oxide film 39, which is the surface facing the dielectric oxynitride film 31 after the nitridation, has a N-polarity, a distance between the channel region 26 and the source electrode 42S and between the channel region 26 and the drain electrode 42D is more likely to become short, achieving low resistance.

When the thickness of the first SiN film 51 is less than 0.2 nm, it may not be able to readily inhibit dissociation of nitrogen from the dielectric oxynitride film 31. When the thickness of the first SiN film 51 is greater than 5 nm, traps in the first SiN film 51 may cause current collapse. The thickness of the first SiN film 51 may be 0.2 nm or greater and 4 nm or less, or may be 0.2 nm or greater and 3 nm or less.

The nitridation of the dielectric oxide film 39 and the formation of the first SiN film 51 may be performed in the same film-forming chamber. By performing the nitridation of the dielectric oxide film 39 and the formation of the first SiN film 51 in the same film-forming chamber, dissociation of nitrogen from the dielectric oxynitride film 31 is readily inhibited before forming the first SiN film 51.

The polarity of the nitride semiconductor layer is not particularly restricted. Specifically, in the case where the nitride semiconductor layer includes gallium, a surface of the nitride semiconductor layer facing the dielectric oxide film may have a gallium-polarity.

Although the embodiments have been described above in detail, the present disclosure is not limited to the above specific embodiments, and various changes and modifications can be made within the scope of the claims.

What is claimed is:

1. A production method for a semiconductor device, comprising:
forming a dielectric oxide film on a nitride semiconductor layer, the dielectric oxide film having a higher relative permittivity than a relative permittivity of silicon dioxide;
nitriding the dielectric oxide film to form a dielectric oxynitride film;
forming a first silicon nitride film on the dielectric oxynitride film by a thermal film formation method;
forming a second silicon nitride film on the first silicon nitride film;
forming an opening in the second silicon nitride film and the first silicon nitride film, the opening reaching the dielectric oxynitride film; and
forming a gate electrode on the second silicon nitride film, the gate electrode being in contact with the dielectric oxynitride film through the opening.

2. The production method according to claim 1,
wherein the dielectric oxide film includes at least one element selected from a group consisting of hafnium, lanthanum, and zirconium.

3. The production method according to claim 2,
wherein the dielectric oxide film further includes at least one element selected from a group consisting of silicon and aluminum.

4. The production method according to claim 1,
wherein a surface of the nitride semiconductor layer facing the dielectric oxide film has a nitrogen-polarity.

5. The production method according to claim 1,
wherein the first silicon nitride film has a thickness of 0.2 nm or greater and 5 nm or less.

6. The production method according to claim 1,
wherein the nitriding of the dielectric oxide film and the forming of the first silicon nitride film are performed in a same film-forming chamber.

7. The production method according to claim 1,
wherein the forming of the second silicon nitride film is performed using a nitrogen plasma.

8. A semiconductor device comprising:
a nitride semiconductor layer;
a dielectric oxynitride film on the nitride semiconductor layer;
a first silicon nitride film on the dielectric oxynitride film;
a second silicon nitride film on the first silicon nitride film;
an opening formed in the second silicon nitride film and the first silicon nitride film, the opening reaching the dielectric oxynitride film; and
a gate electrode on the second silicon nitride film, the gate electrode being in contact with the dielectric oxynitride film through the opening.

9. The semiconductor device according to claim 8,
wherein the first silicon nitride film has a lower hydrogen atom concentration than a hydrogen atom concentration of the second silicon nitride film.

10. The semiconductor device according to claim 8,
wherein the first silicon nitride film has a higher density than a density of the second silicon nitride film.
